(19) United States
(12) Patent Application Publication
(10) Pub. No.: US 2025/0089575 A1
(43) Pub. Date: Mar. 13, 2025

(54) METHOD FOR MANUFACTURING SPINTRONIC DEVICE

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Jiun-Yun LI, Taipei City (TW); Yu-Jui WU, Taipei City (TW); Chia-You LIU, Taipei City (TW); Chia-Tse TAI, Tainan City (TW); Tsung-Ying LI, Changhua County (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 18/464,487

(22) Filed: Sep. 11, 2023

(51) Int. Cl. H10N 50/01; H10N 50/20

(52) U.S. Cl. CPC H10N 50/01; H10N 50/20

(57) ABSTRACT

A method includes epitaxially growing a Ge₁₋ₓSnₓ channel layer over a substrate. The Ge₁₋ₓSnₓ channel layer is in a metastable state. A Ge_{1-y}Sn_{y} barrier layer is epitaxially grown over the Ge₁₋ₓSnₓ channel layer to form a two-dimensional hole gas in the Ge₁₋ₓSnₓ channel layer. The Ge₁₋ₓSnₓ channel layer and the Ge_{1-y}Sn_{y} barrier layer are etched to form a first opening and a second opening in the Ge₁₋ₓSnₓ channel layer and the Ge_{1-y}Sn_{y} barrier layer. A first source/drain electrode and a second source/drain electrode are deposited in the first opening and the second opening, respectively. A gate electrode is formed over the Ge_{1-y}Sn_{y} barrier layer.

### BACKGROUND

Quantum computing refers to the field of research related to computation systems that use quantum mechanical phenomena to manipulate data. On the roadmap towards building a scalable, silicon-based quantum computer, several milestones have already been achieved. Quantum computing may involve initializing states of N qubits (quantum bits), creating controlled entanglements among them, allowing these states to evolve, and reading out the states of the qubits after the evolution. A qubit is may be a system having two degenerate (i.e., of equal energy) quantum states, with a non-zero probability of being found in either state. Thus, N qubits can define an initial state that is a combination of 2^{N} classical states.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-4B illustrate top views and cross-sectional views of intermediate stages in the formation of a spintronic device in accordance with some embodiments of the present disclosure.

FIG. 5 shows simulated densities of holes in GeSn layers versus spin-orbit energies (Δ_{SO}) under different gate voltages according to some embodiments of the present disclosure.

FIG. 6 shows simulated stress difference (F) at different [Sn] in channel layer and different [Sn] in buffer layer according to some embodiments of the present disclosure.

FIGS. 7A-11B illustrate top views and cross-sectional views of intermediate stages in the formation of a spintronic device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The embodiments of the present disclosure provide spintronic devices including a channel stack having a strong spin-orbit coupling (SOC) effect to improve the quantum computing efficiency of the spintronic devices. Further, the SOC of the channel stack can be tuned by varying the gate bias of the spintronic devices and/or the components of the materials of the channel stack. In some embodiments, transistors used in the spintronic devices may be realized on the device selected from the group including planar devices, multi-gate devices, FinFETs, nanosheet-gate FETs, and gate-all-around FETs.

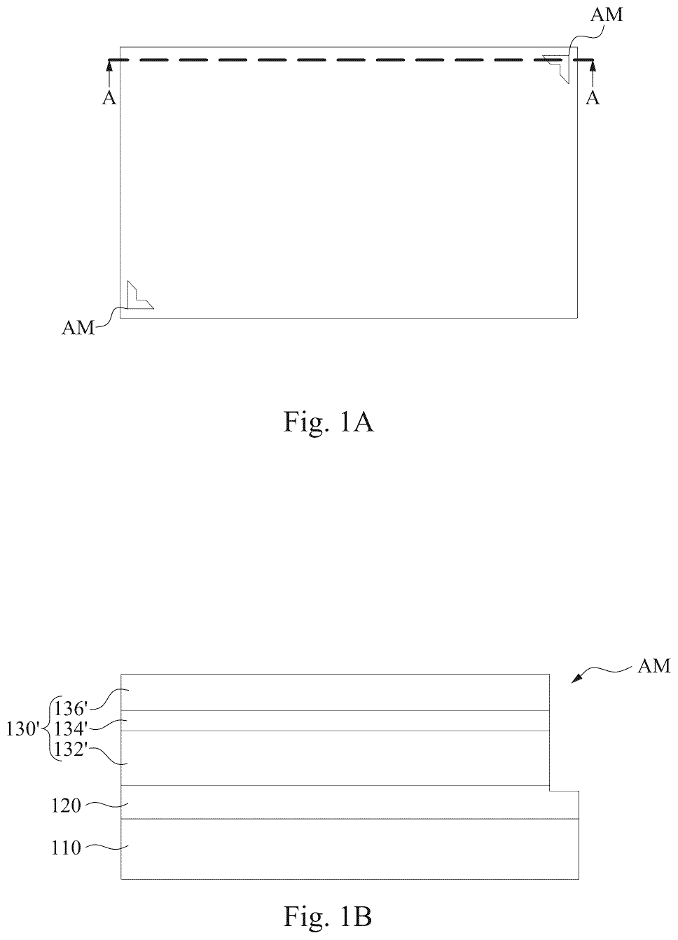

FIGS. 1A-4B illustrate top views and cross-sectional views of intermediate stages in the formation of a spintronic device 100 in accordance with some embodiments of the present disclosure. Throughout the various views and illustrative embodiments, like reference numbers are used to designate like elements. It is understood that additional operations can be provided before, during, and after the processes shown by FIGS. 1A-4B, and some of the operations described below can be replaced or eliminated, for additional embodiments of the method. The order of the operations/processes may be interchangeable.

Reference is made to FIGS. 1A and 1B, where FIG. 1B is a cross-sectional view taken along line A-A of FIG. 1A. A substrate 110 is provided or received. In some embodiments, the substrate 110 may include silicon (Si). Alternatively, the substrate 110 may include germanium (Ge), silicon germanium, gallium arsenide (GaAs), or other appropriate semiconductor materials. In some alternative embodiments, the substrate 110 may include an epitaxial layer with or without dopants. Furthermore, the substrate 110 may include a semiconductor-on-insulator (SOI) structure having a buried dielectric layer therein. The buried dielectric layer may be, for example, a buried oxide (BOX) layer. The SOI structure may be formed by a method referred to as separation by implantation of oxygen technology, wafer bonding, selective epitaxial growth (SEG), or other appropriate method.

A base buffer layer 120 is formed over the substrate 110. The base buffer layer 120 and the substrate 110 are made of different materials. In some embodiments, the base buffer layer 120 includes an epitaxially grown layer. The epitaxially grown layer may include IV group compound materials, Ge and/or other suitable materials. In some embodiments, the base buffer layer 120 is in contact with the substrate 110 and has a material different from the material of the substrate 110. For example, the base buffer layer 120 is a substantially pure Ge layer (e.g., greater than 90 atomic percentage of Ge) while the substrate 110 is a substantially pure Si layer (e.g., greater than 90 atomic percentage of Si). The base buffer layer 120 is configured to reduce the lattice mismatch between the substrate 110 and the layer formed thereon (e.g., the channel stack 130). The term “substantially” as used herein may be applied to modify any quantitative representation which could permissibly vary without resulting in a change in the basic function to which it is related.

An epitaxial stack 130′ is formed over the base buffer layer 120. In some embodiments, the epitaxial stack 130′ includes a first epitaxial layer 132′, a second epitaxial layer 134′, and a third epitaxial layer 136′. In some embodiments, the first epitaxial layer 132′, the second epitaxial layer 134′, and the third epitaxial layer 136′ are made of IV-IV compound materials. The first epitaxial layer 132′, the second epitaxial layer 134′, and the third epitaxial layer 136′ may be formed by one or more epitaxy processes, e.g., selective epitaxial growth in any suitable epitaxial deposition system, including, but not limited to, metal-organic chemical vapor deposition (MOCVD), atmospheric-pressure CVD (APCVD), low- (or reduced-) pressure CVD (LPCVD), ultra-high-vacuum CVD (UHVCVD), molecular beam epitaxy (MBE), or atomic layer deposition (ALD). In some embodiments, the first epitaxial layer 132′, the second epitaxial layer 134′, and the third epitaxial layer 136′ are in metastable states.

Subsequently, an etching process is performed to form alignment marks AM in the epitaxial stack 130′. For example, a patterned mask layer is formed over the epitaxial stack 130′, and the etching process is performed by using the patterned mask layer as an etching mask to form the alignment marks AM in the epitaxial stack 130′. In FIGS. 1A and 1B, the alignment marks AM are trenches, openings, recesses, or other suitable structures.

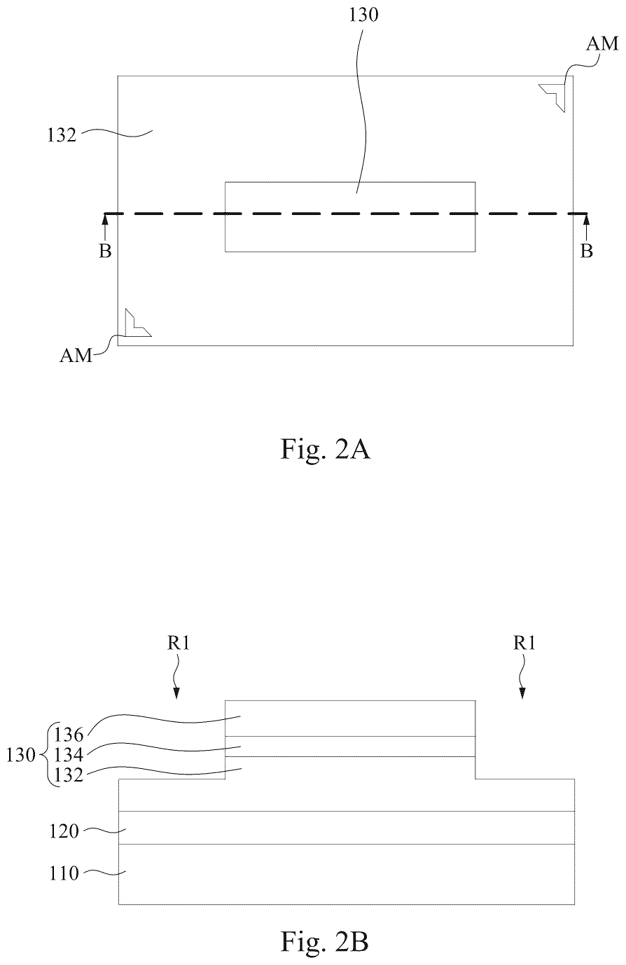

Reference is made to FIGS. 2A and 2B, where FIG. 2B is a cross-sectional view taken along line B-B of FIG. 2A. Another etching process is performed to pattern the epitaxial stack 130′ into a channel stack 130 over the base buffer layer 120. Therefore, the channel stack 130 includes a first epitaxial layer 132, a second epitaxial layer 134, and a third epitaxial layer 136. In some embodiments, the channel stack 130 has a bar shape, a rectangular shape, a strip shape, or other suitable shape in the top view (see FIG. 2A). Therefore, the channel stack 130 can be considered to be a one-dimensional (1D) channel. The etching process forms a recess R1 to surround the channel stack 130. In some embodiments, the recess R1 extends through the third epitaxial layer 136 and the second epitaxial layer 134 but not the first epitaxial layer 132. However, in some other embodiments, the recess R1 may extends through the first epitaxial layer 132 as well. Further, the alignment marks AM may be deeper than the recess R1 as shown in FIG. 2A and FIGS. 1B and 2B.

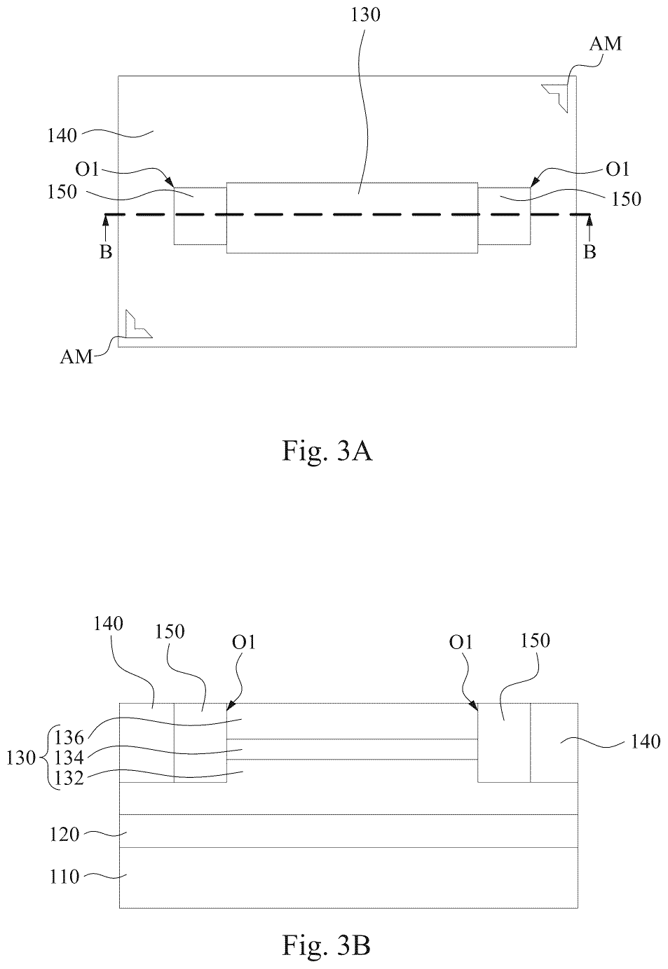

Reference is made to FIGS. 3A and 3B, where FIG. 3B is a cross-sectional view taken along line B-B of FIG. 3A. A first dielectric layer 140 is formed over the base buffer layer 120 and in the recess R1 (see FIG. 2B). In some embodiments, the first dielectric layer 140 include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The first dielectric layer 140 may be deposited by a PECVD process or other suitable deposition technique.

Next, openings O1 are formed in the first dielectric layer 140 and at opposite ends of the channel stack 130. Therefore, the openings O1 expose the end sidewalls of the channel stack 130. For example, another patterned mask layer is formed over the channel stack 130 and the first dielectric layer 140, and an etching process is performed by using the patterned mask layer as an etching mask to form the openings O1. In some embodiments, the etching process is a selective etching process which etches the first dielectric layer 140 at a rate faster than etches the channel stack 130.

Thereafter, source/drain electrodes 150 are formed in the openings O1, respectively. The source/drain electrodes 150 may be ferromagnetic materials, such as Fe, Co, Ni, FeCo, CoNi, CoFeB, FeB, FePt, FePd, combinations thereof, or the like. In some embodiments, one of the source/drain electrodes 150 acts as a spin filter, and another one of the source/drain electrodes 150 acts as a spin detector.

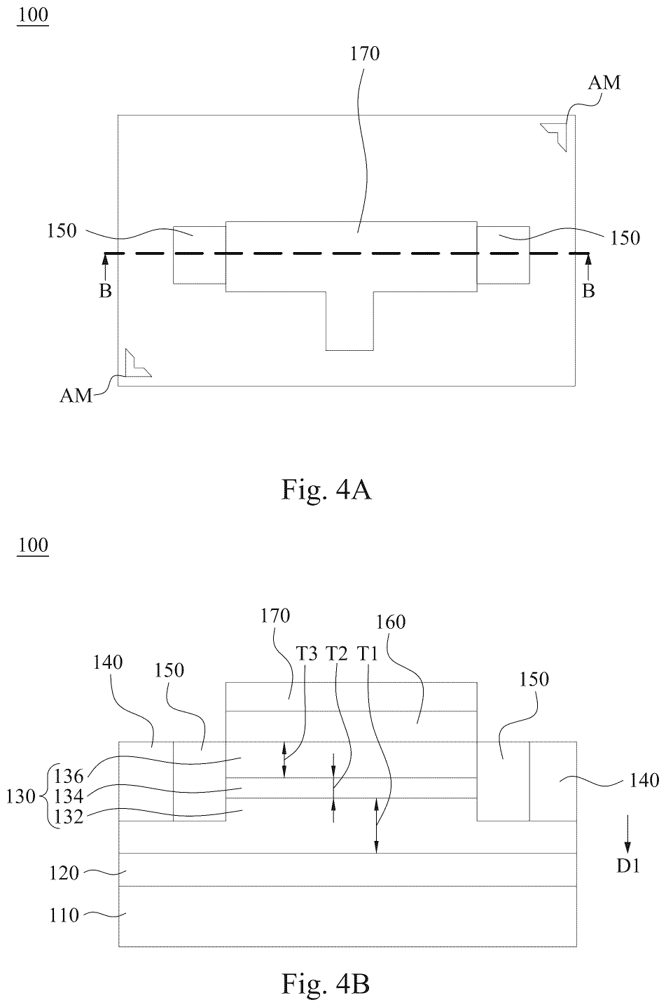

Reference is made to FIGS. 4A and 4B, where FIG. 4B is a cross-sectional view taken along line B-B of FIG. 4A. A gate dielectric layer 160 and a gate electrode 170 are formed over the channel stack 130. For example, a dielectric layer and a conductive layer are sequentially formed over the structure as shown in FIGS. 3A and 3B, and the conductive layer and the dielectric layer are then patterned to form the gate electrode 170 and the gate dielectric layer 160. In some embodiments, the gate dielectric layer 160 may include silicon dioxide, silicon nitride, or other suitable material. Alternatively, the gate dielectric layer 160 can be a high-κ dielectric layer having a dielectric constant (x) higher than the dielectric constant of SiO₂, i.e. κ>3.9. The gate dielectric layer 160 may include LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Si₃N₄, oxynitrides (SiON), or other suitable materials. The gate dielectric layer 160 is deposited by suitable techniques, such as ALD, CVD, PVD, thermal oxidation, combinations thereof, or other suitable techniques.

The gate electrode 170 is formed over the gate dielectric layer 160. The gate electrode 170 includes one or more layers of conductive material. Examples of the gate electrode 170 include W, Ti, TiAlC, Al, TiAl, TaN, TaAlC, TiN, TiC, Co, TaC, Al, TiAl, HfTi, TiSi, TaSi, TiAlC, combinations thereof, or the like. The gate electrode 170 may be formed by chemical vapor deposition (CVD), physical vapor deposition (PVD) including sputtering, atomic layer deposition (ALD) or other suitable method.

In FIGS. 4A and 4B, the spintronic device 100 is a spin FET and includes the channel stack 130, the source/drain electrodes 150, and the gate electrode 170. The source/drain electrodes 150 are on opposite sides of the channel stack. Further, the source/drain electrodes 150 are in contact with and connected to the second epitaxial layer 134, and the gate electrode 170 is over the channel stack 130. The channel stack 130 includes the first epitaxial layer 132, the second epitaxial layer 134 over the first epitaxial layer 132, and the third epitaxial layer 136 over the second epitaxial layer 134. The first epitaxial layer 132 and the second epitaxial layer 134 are made of the same IV-IV group compound materials but have different concentrations. Similarly, the third epitaxial layer 136 and the second epitaxial layer 134 are made of the same IV-IV group compound materials but have different concentrations. Therefore, the first epitaxial layer 132, the second epitaxial layer 134, and the third epitaxial layer 136 form a heterostructure. Due to the first epitaxial layer 132, the second epitaxial layer 134, and the third epitaxial layer 136 are IV-IV group compound materials, the spintronic device 100 can be applied to and compatible to silicon-based devices, e.g., silicon-based FinFETs, silicon-based GAA FETs, or the like.

In some embodiments, the IV-IV group compound materials are metal-containing binary compound materials including a IV group semiconductor element and a IV group metal element. For example, the first epitaxial layer 132 is made of Ge_{1-y}Sn_{y}, the second epitaxial layer 134 is made of Ge₁₋ₓSnₓ, the third epitaxial layer 136 is made of Ge_{1-z}Sn_{z}, and x is greater than y and z. In some embodiments, y is equal to z. That is, the Ge atomic percentage in the second epitaxial layer 134 is lower than the Ge atomic percentage in the first epitaxial layer 132 and also lower than the Ge atomic percentage in the third epitaxial layer 136. Therefore, the second epitaxial layer 134 is a strained layer. Such configuration forms a quantum well (QW) in the second epitaxial layer 134, and a two-dimensional hole gas (2DHG) can be formed in the second epitaxial layer 134. As such, the second epitaxial layer 134 may be referred to as a channel layer, the third epitaxial layer 136 may be referred to as a barrier layer or a top buffer layer, and the first epitaxial layer 132 may be referred to as a bottom buffer layer.

As mentioned above, the first epitaxial layer 132, the second epitaxial layer 134, and the third epitaxial layer 136 may be in metastable states. The Sn atomic percentage (i.e., metal atomic percentage) in the metastable state may be up to about 30%. That is, in some embodiments, 0≤y<x≤30%, and 0≤z<x≤30%. Compared with pure Ge layers, Sn atoms in the channel stack 130 increase the (Rashba) SOC, which is the interaction between the electron's spin and its orbital motion around the nucleus, therein. With an enough strong SOC, the gate electrode 170 can effectively control the spin of the carriers (e.g., holes in this case) in the second epitaxial layer 134, and a magnetic material which provides a magnetic field for spin control can be omitted. As such, a size of the spintronic device 100 can be reduced. Further, the stronger the SOC, the faster the spin manipulation rates of the spintronic device 100, leading to faster data rates of the spin FET.

As mentioned above, the third epitaxial layer 136 is made of IV-IV group compound materials, such that there is substantially free of N-type and P-type dopants in the third epitaxial layer 136. For example, the atomic percentage of the N-type and/or P-type dopants in the third epitaxial layer 136 is lower than about 0.01%. Without the N-type and P-type dopants, the carrier concentration in the second epitaxial layer 134 can be tuned by the voltage (or bias) of the gate electrode 170. In greater detail, when a bias is applied to the gate electrode 170, an electric field is formed in the channel stack 130. If the third epitaxial layer 136 includes sufficient amount of N-type and/or P-type dopants, the dopants would shield the electric field, and the second epitaxial layer 134 may be less sensible to the variation of the bias. However, in this case, since the third epitaxial layer 136 is made of IV-IV group compound materials without enough amount of N-type and/or P-type dopants, the third epitaxial layer 136 does not shield the electric field. When the bias of the gate electrode 170 varies, the carrier concentration of the second epitaxial layer 134 changes (increases for example) as well. With a higher carrier concentration, the SOC gets stronger.

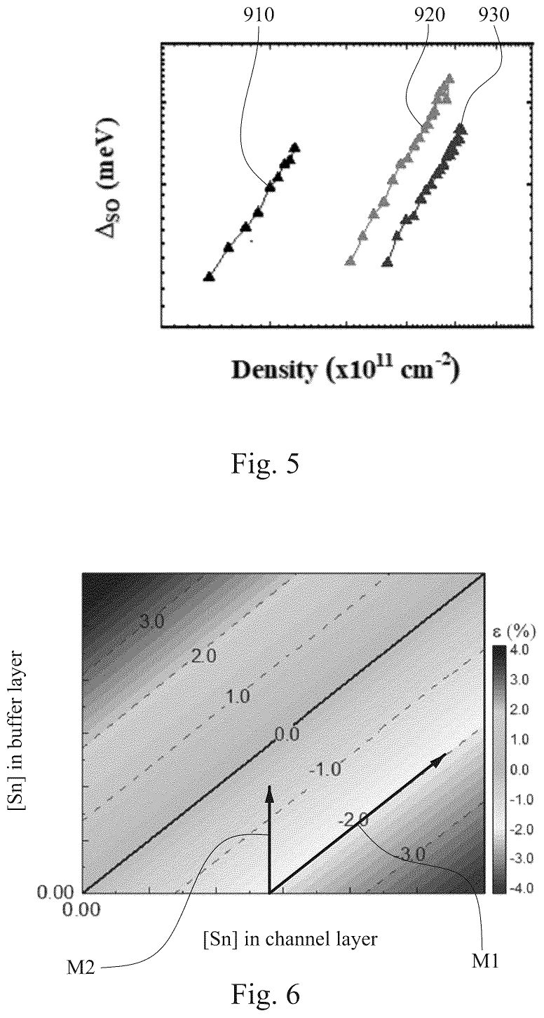

FIG. 5 shows simulated densities of holes in GeSn layers versus spin-orbit energies (Δ_{SO}) under different gate voltages according to some embodiments of the present disclosure. Data 910 illustrates the density of holes in the Ge₁₋ₓ₁Snₓ₁ channel layer under different gate voltages, data 920 illustrates the density of holes in the Ge₁₋ₓ₂Snₓ₂ channel layer under different gate voltages, and data 930 illustrates the density of holes in the Ge₁₋ₓ₃Snₓ₃ channel layer under different gate voltages, where x3>x2>x1. As shown in FIG. 5, as the gate voltage varies, the density of holes in the GeSn channel layer changes as well. As the density of holes increases, the spin-orbit energy Δ_{SO} increases, and the SOC increases as well.

In some embodiments, the SOC of the channel stack 130 can be tuned by tuning the Sn concentration (or Sn atomic percentage or [Sn]) and/or the stress difference (P) among the first epitaxial layer 132, the second epitaxial layer 134, and the third epitaxial layer 136. FIG. 6 shows simulated stress difference (P) at different [Sn] in channel layer and different [Sn] in buffer layer according to some embodiments of the present disclosure. In FIGS. 4B and 6, when x>y and/or x>z, the stress difference between the second epitaxial layer 134 and the first epitaxial layer 132 (and/or the third epitaxial layer 136) is negative, and the second epitaxial layer 134 has a compressive strain to form the 2DHG therein.

The [Sn] in the channel stack 130 can be determined in different ways. For example, in some embodiments, as shown as the path M1 in FIG. 6, the difference between the [Sn] in the second epitaxial layer 134 (channel layer) and [Sn] in the first and third epitaxial layer 132 and 136 (buffer layer) can be fixed. That is, [Sn] in the first and third epitaxial layer 132 and 136 (i.e., the y value and the z value) varies as [Sn] in the second epitaxial layer 134 varies. With the constant values of (x-y) and (x-z), when the values x, y, and z increase as shown in the path M1, the SOC of the channel stack 130 increases. In some embodiments, (x-y) and/or (x-z) is(are) in a range from about 0% to about 30%. If (x-y) and/or (x-z) is(are) higher than about 30%, the stress in the channel stack 130 may be too severe, thereby damaging the channel stack 130; if (x-y) and/or (x-z) is(are) lower than about 0%, QW may not be formed in the second epitaxial layer 134. In some other embodiments, as shown as the path M2 in FIG. 6, the [Sn] in the second epitaxial layer 134 is fixed, and [Sn] in the first and third epitaxial layer 132 and 136 are increased, such that the stress (P) is decreased. In this scenario, the SOC of the channel stack 130 increases as well.

As shown in FIG. 4B, in some embodiments, the first epitaxial layer 132 has a thickness T1, the second epitaxial layer 134 has a thickness T2, and the third epitaxial layer 136 has a thickness T3. The thickness T2 of the second epitaxial layer 134 is in a range from about 2 nm to about 30 nm. If the thickness T2 is less than about 2 nm, the quantum well may not be formed in the second epitaxial layer 134; if the thickness T2 is greater than about 30 nm, the stress in the second epitaxial layer 134 may damage the second epitaxial layer 134. Moreover, the thickness T1 is greater than the thickness T2, and the thickness T3 is greater than the thickness T2. As such, the stress of the second epitaxial layer 134 is dominated by the first epitaxial layer 132 and/or the third epitaxial layer 136.

In some embodiments, the [Sn] in the first epitaxial layer 132 decreases in the depth direction D1. For example, the [Sn] is about 0 at the bottom surface of the first epitaxial layer 132, and the [Sn] is about y at the top surface of the first epitaxial layer 132. Therefore, the first epitaxial layer 132 can release the lattice mismatch between the second epitaxial layer 134 and the base buffer layer 120. In some embodiments, the thickness T1 is greater than the thickness T2 and T3 for providing a sufficient thickness to form a [Sn] gradient in the first epitaxial layer 132.

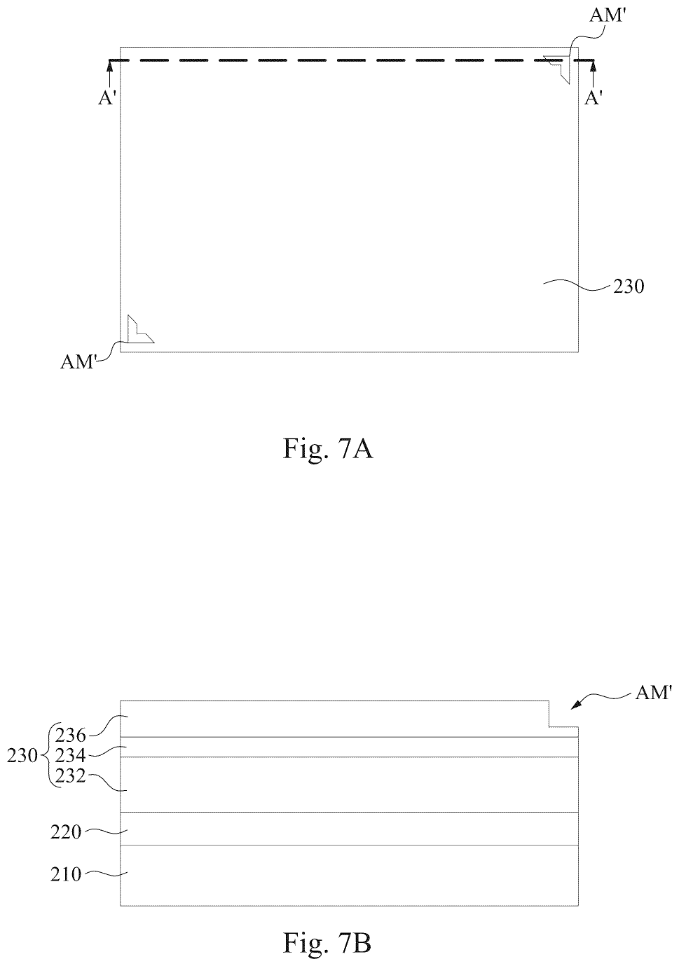

FIGS. 7A-11B illustrate top views and cross-sectional views of intermediate stages in the formation of a spintronic device 200 in accordance with some embodiments of the present disclosure. Throughout the various views and illustrative embodiments, like reference numbers are used to designate like elements. It is understood that additional operations can be provided before, during, and after the processes shown by FIGS. 7A-11B, and some of the operations described below can be replaced or eliminated, for additional embodiments of the method. The order of the operations/processes may be interchangeable.

Reference is made to FIGS. 7A and 7B, where FIG. 7B is a cross-sectional view taken along line A′-A′ of FIG. 7A. A substrate 210 is provided. The substrate 210 is similar to or the same as the substrate 110 in FIG. 1B. A base buffer layer 220 is formed over the substrate 210. The base buffer layer 220 is similar to or the same as the base buffer layer 120 in FIG. 1B. Thereafter, a channel stack 230 is formed over the base buffer layer 220. The channel stack 230 includes a first epitaxial layer 232 over the base buffer layer 220, a second epitaxial layer 234 over the first epitaxial layer 232, and a third epitaxial layer 236 over the second epitaxial layer 234. The first epitaxial layer 232 is similar to or the same as the first epitaxial layer 132 in FIG. 1B, the second epitaxial layer 234 is similar to or the same as the second epitaxial layer 134 in FIG. 1B, and the third epitaxial layer 236 is similar to or the same as the third epitaxial layer 136 in FIG. 1B.

In some embodiments, an etching process is performed to form alignment marks AM′ in the channel stack 230. For example, a patterned mask layer is formed over the channel stack 230, and the etching process is performed by using the patterned mask layer as an etching mask to form the alignment marks in the channel stack 230. In FIGS. 7A and 7B, the alignment marks AM′ are trenches, openings, recesses, or other suitable structures.

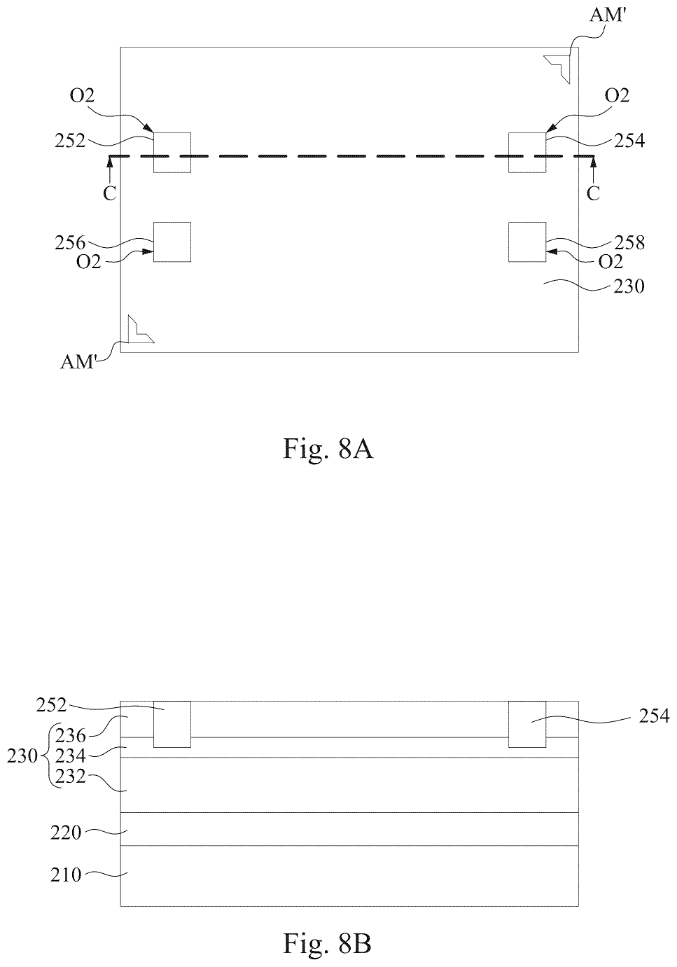

Reference is made to FIGS. 8A and 8B, where FIG. 8B is a cross-sectional view taken along line C-C of FIG. 8A. Openings O2 are formed in the channel stack 230. For example, another patterned mask layer is formed over the channel stack 230, and an etching process is performed by using the patterned mask layer as an etching mask to form the openings O2. In some embodiments, the openings O2 extend through the third epitaxial layer 236 but not the second epitaxial layer 234. However, in some other embodiments, the openings O2 may extend through the second epitaxial layer 234 (and the first epitaxial layer 232) as well.

Subsequently, source/drain electrodes 252, 254, 256, and 258 are formed in the openings O2, respectively. For example, conductive materials are filled in the openings O2, and then a CMP process or an etching back process is performed to remove portions of the conductive materials outside the openings O2, such that source/drain electrodes 252, 254, 256, and 258 are embedded by the channel stack 230. In some embodiments, the conductive materials (and thus the source/drain electrodes 252, 254, 256, and 258) are made of W, Ti, TiAlC, Al, TiAl, TaN, TaAlC, TiN, TiC, Co, TaC, Al, TiAl, HfTi, TiSi, TaSi, TiAlC, combinations thereof, or the like. The conductive materials may be deposited by chemical vapor deposition (CVD), physical vapor deposition (PVD) including sputtering, atomic layer deposition (ALD) or other suitable method.

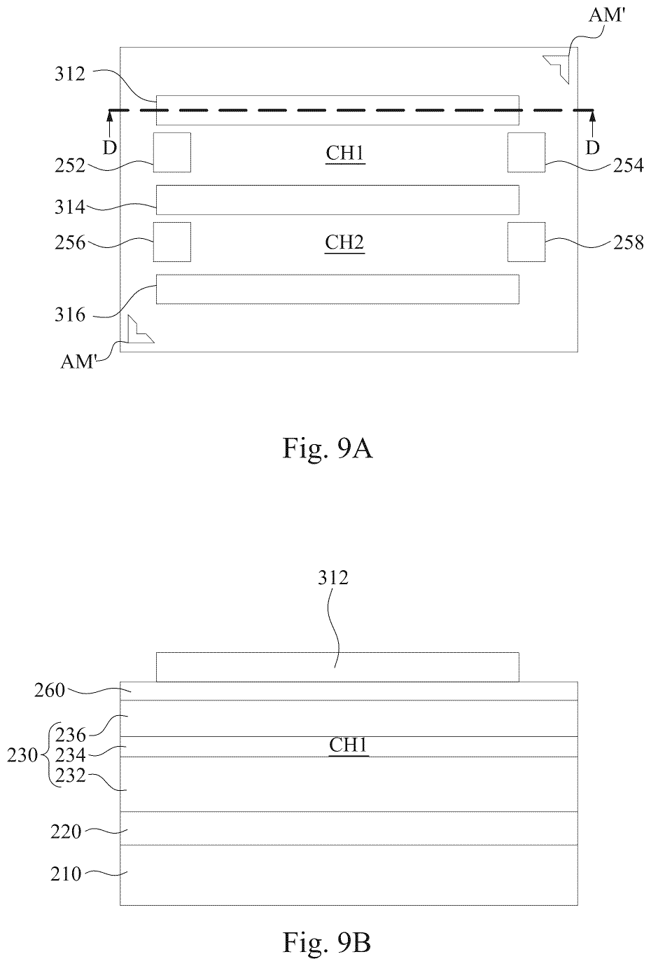

Reference is made to FIGS. 9A and 9B, where FIG. 9B is a cross-sectional view taken along line D-D of FIG. 9A. A first gate dielectric layer 260 is deposited over the channel stack 230 and the source/drain electrodes 252, 254, 256, and 258. For clarity, the first gate dielectric layer 260 is not shown in FIG. 9A, and the elements covered by the first gate dielectric layer 260 are illustrated in FIG. 9A as well. The first gate dielectric layer 260 is similar to or the same as the gate dielectric layer 160 in FIG. 4B. Thereafter, confinement gates 312, 314, and 316 are formed over the first gate dielectric layer 260. For example, a conductive layer is deposited over the first gate dielectric layer 260 and then patterned to form the confinement gates 312, 314, and 316. The conductive layer (and thus the confinement gates 312, 314, and 316) is made of W, Ti, TiAlC, Al, TiAl, TaN, TaAlC, TiN, TiC, Co, TaC, Al, TiAl, HfTi, TiSi, TaSi, TiAlC, combinations thereof, or the like. The conductive layer may be deposited by chemical vapor deposition (CVD), physical vapor deposition (PVD) including sputtering, atomic layer deposition (ALD) or other suitable method.

In some embodiments, each of the confinement gates 312, 314, and 316 has a bar shape, a rectangular shape, a strip shape, or other suitable shape in the top view (see FIG. 9A). The confinement gates 312, 314, and 316 are configured to confine current paths in the channel stack 230. Specifically, the confinement gates 312, 314, and 316 prevent carriers (e.g., electrons and/or holes) from flowing through regions right under the confinement gates 312, 314, and 316. Therefore, the confinement gates 312, 314, and 316 define channel regions CH1 and CH2 of the spintronic device 200. As shown in FIG. 9A, a pair of the source/drain electrodes 252 and 254 is between the adjacent two confinement gates 312 and 314, which define the channel region CH1 therebetween and between the source/drain electrodes 252 and 254. As such, current is able to flow from one of the source/drain electrodes 252 and 254, through the channel region CH1, to another one of the source/drain electrodes 252 and 254. Similarly, a pair of the source/drain electrodes 256 and 258 is between the adjacent two confinement gates 314 and 316, which define the channel region CH2 therebetween and between the source/drain electrodes 256 and 258. As such, current is able to flow from one of the source/drain electrodes 256 and 258, through the channel region CH2, to another one of the source/drain electrodes 256 and 258.

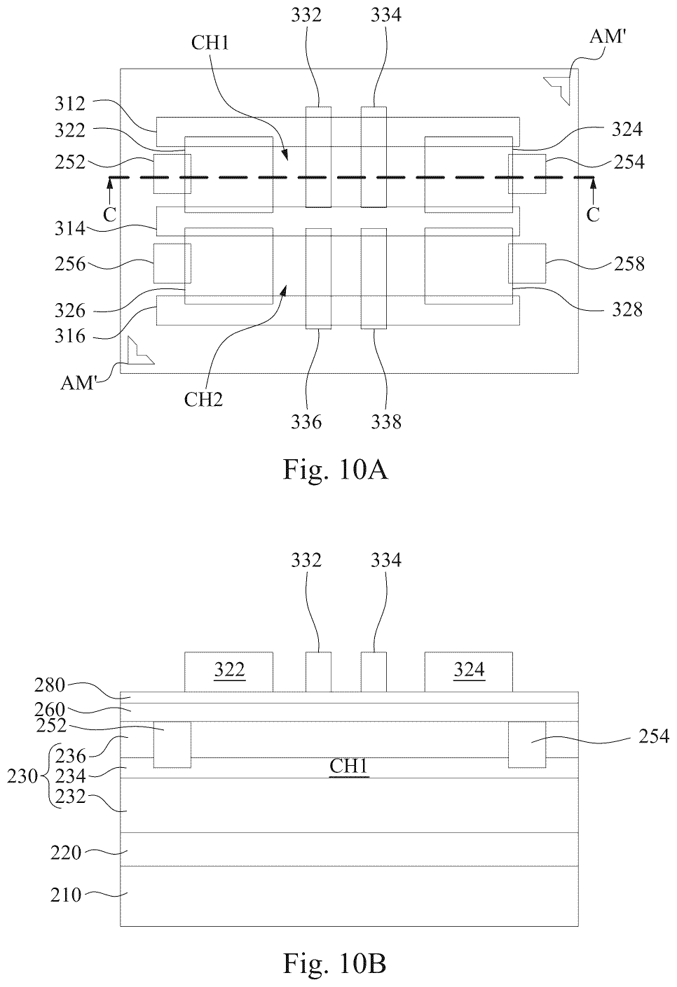

Reference is made to FIGS. 10A and 10B, where FIG. 10B is a cross-sectional view taken along line C-C of FIG. 10A. A second gate dielectric layer 280 is deposited over the first gate dielectric layer 260 and the confinement gates 312, 314, and 316. For clarity, the second gate dielectric layer 280 is not shown in FIG. 10A, and the elements covered by the second gate dielectric layer 280 are illustrated in FIG. 10A as well. The second gate dielectric layer 280 is similar to or the same as the first gate dielectric layer 260 in FIG. 9B. Thereafter, extension gates 322, 324, 324, and 328 and accumulation gates 332, 334, 336, and 338 are formed over the second gate dielectric layer 280. For example, another conductive layer is deposited over the second gate dielectric layer 280 and then patterned to form the extension gates 322, 324, 324, and 328 and the accumulation gates 332, 334, 336, and 338. The conductive layer (and thus the extension gates 322, 324, 324, and 328 and the accumulation gates 332, 334, 336, and 338) is made of W, Ti, TiAlC, Al, TiAl, TaN, TaAlC, TiN, TiC, Co, TaC, Al, TiAl, HfTi, TiSi, TaSi, TiAlC, combinations thereof, or the like. The conductive layer may be deposited by chemical vapor deposition (CVD), physical vapor deposition (PVD) including sputtering, atomic layer deposition (ALD) or other suitable method.

As shown in FIG. 10A, the accumulation gates 332 and 334 are formed over and across the channel region CH1 and the confinement gates 312 and 314, and the accumulation gates 336 and 338 are formed over and across the channel region CH2 and the confinement gates 314 and 316. The extension gate 322 is between the accumulation gate 332 and the source/drain electrode 252 in the top view, the extension gate 324 is between the accumulation gate 334 and the source/drain electrode 254 in the top view, the extension gate 326 is between the accumulation gate 336 and the source/drain electrode 256 in the top view, and the extension gate 328 is between the accumulation gate 338 and the source/drain electrode 258 in the top view. Carriers (holes in this case) can be stored in the channel regions CH1 and CH2 and under the accumulation gates 332, 334, 336, and 338, respectively, and each of the stored carriers under the accumulation gates 332, 334, 336, and 338 is a qubit.

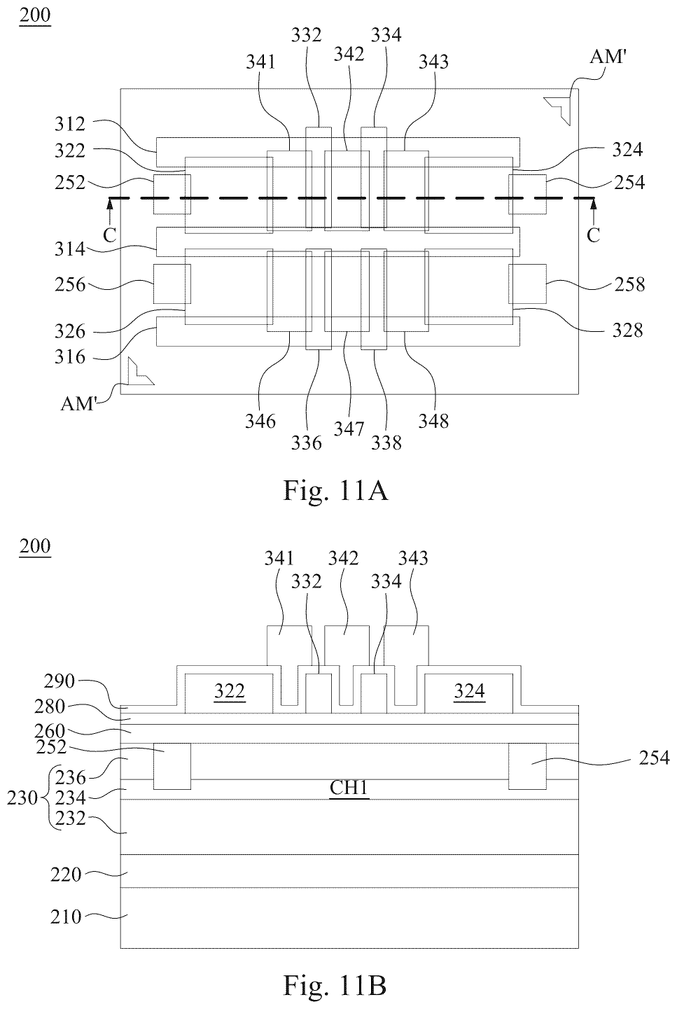

Reference is made to FIGS. 11A and 11B, where FIG. 11B is a cross-sectional view taken along line C-C of FIG. 11A. A third gate dielectric layer 290 is deposited over the second gate dielectric layer 280, the extension gates 322, 324, 324, 328, and the accumulation gates 332, 334, 336, 338. For clarity, the third gate dielectric layer 290 is not shown in FIG. 11A, and the elements covered by the third gate dielectric layer 290 are illustrated in FIG. 11A as well. The third gate dielectric layer 290 is similar to or the same as the first gate dielectric layer 260 in FIG. 9B. Thereafter, bridge gates 341, 342, 343, 346, 347, and 348 are formed over the third gate dielectric layer 290. For example, another conductive layer is deposited over the third gate dielectric layer 290 and then patterned to form the bridge gates 341, 342, 343, 346, 347, and 348. The conductive layer (and thus the bridge gates 341, 342, 343, 346, 347, and 348) is made of W, Ti, TiAlC, Al, TiAl, TaN, TaAlC, TiN, TiC, Co, TaC, Al, TiAl, HfTi, TiSi, TaSi, TiAlC, combinations thereof, or the like. The conductive layer may be deposited by chemical vapor deposition (CVD), physical vapor deposition (PVD) including sputtering, atomic layer deposition (ALD) or other suitable method.

The bridge gate 341 is between the extension gate 322 and the accumulation gate 332, the bridge gate 342 is between the accumulation gates 332 and 334, the bridge gate 343 is between the accumulation gate 334 and the extension gate 324, the bridge gate 346 is between the extension gate 326 and the accumulation gate 336, the bridge gate 347 is between the accumulation gates 336 and 338, and the bridge gate 348 is between the accumulation gate 338 and the extension gate 328. When biases are applied to the bridge gates 341 and 342 and the extension gate 322, a single carrier can flow from the source/drain electrode 252 to the channel region CH1 right under the accumulation gate 334; when biases are applied to the bridge gate 341 and the extension gate 322, a single carrier can flow from the source/drain electrode 252 to the channel region CH1 right under the accumulation gate 332; when biases are applied to the bridge gate 343 and the extension gate 324, the qubit stored right under the accumulation gate 334 can flow to the source/drain electrode 254; when biases are applied to the bridge gates 342 and 343 and the extension gate 324, the qubit stored right under the accumulation gate 332 can flow to the source/drain electrode 254. Similarly, when biases are applied to the bridge gates 346 and 347 and the extension gate 326, a single carrier can flow from the source/drain electrode 256 to the channel region CH2 right under the accumulation gate 338; when biases are applied to the bridge gate 346 and the extension gate 326, a single carrier can flow from the source/drain electrode 256 to the channel region CH2 right under the accumulation gate 336; when biases are applied to the bridge gate 348 and the extension gate 328, the qubit stored right under the accumulation gate 338 can flow to the source/drain electrode 258; when biases are applied to the bridge gates 347 and 348 and the extension gate 328, the qubit stored right under the accumulation gate 336 can flow to the source/drain electrode 258.

As shown in FIGS. 11A and 11B, the spintronic device 200 is a spin qubit device and includes the channel stack 230, the source/drain electrodes 252, 254, 256, and 258, the extension gates 322, 324, 326, and 328, the accumulation gates 332, 334, 336, and 338, and the bridge gates 341, 342, 343, 346, 347, and 348. By controlling the biases of the accumulation gates 332, 334, 336, and 338, the spin orientation of the corresponding qubit can be controlled. Also, as mentioned above, by controlling [Sn] and/or the values of (x-y) and (x-z), the SOC of the channel stack 230 can be increased, and the qubit fidelity of the spintronic device 200 gets higher.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the channel stack of the spintronic device has strong SOC, leading to higher qubit fidelity and faster data rates thereof. In addition, since the channel stack is made of IV-IV group compound materials, the spintronic devices can be compatible with the silicon-based devices. Furthermore, the spin orientation of the spintronic devices is controlled by gates, such that the size of the spintronic devices can be reduced.

According to some embodiments, a method includes epitaxially growing a Ge₁₋ₓSnₓ channel layer over a substrate. The Ge₁₋ₓSnₓ channel layer is in a metastable state. A Ge_{1-y}Sn_{y} barrier layer is epitaxially grown over the Ge₁₋ₓSnₓ channel layer to form a two-dimensional hole gas in the Ge₁₋ₓSnₓ channel layer. The Ge₁₋ₓSnₓ channel layer and the Ge_{1-y}Sn_{y} barrier layer are etched to form a first opening and a second opening in the Ge₁₋ₓSnₓ channel layer and the Ge_{1-y}Sn_{y} barrier layer. A first source/drain electrode and a second source/drain electrode are deposited in the first opening and the second opening, respectively. A gate electrode is formed over the Ge_{1-y}Sn_{y} barrier layer.

According to some embodiments, a method includes receiving a substrate. A first epitaxy process is performed to form a channel layer over the substrate. The channel layer includes Sn and Ge and has a first Sn atomic percentage. A second Sn atomic percentage in a barrier layer is determined based on the first Sn atomic percentage of the channel layer for increasing a spin-orbit coupling effect of the channel layer. A second epitaxy process is performed to form the barrier layer with the second Sn atomic percentage over and in contact with the channel layer. A first source/drain electrode and a second source/drain electrode are formed in the channel layer and the barrier layer. A gate electrode is formed to cover the barrier layer and between the first source/drain electrode and the second source/drain electrode.

According to some embodiments, a method includes epitaxially growing a channel stack over a substrate. The channel stack is a heterostructure and includes a channel layer including a first metal-containing binary compound material and a barrier layer in contact with the channel layer and including a second metal-containing binary compound material. A metal atomic percentage of the first metal-containing binary compound material is higher than a metal atomic percentage of the second metal-containing binary compound material. The method further includes forming source/drain electrodes over the substrate and in contact with the channel layer; depositing a gate dielectric layer to cover the channel stack; and forming a gate electrode over the gate dielectric layer and the channel stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
epitaxially growing a Ge₁₋ₓSnₓ channel layer over a substrate, wherein the Ge₁₋ₓSnₓ channel layer is in a metastable state;
epitaxially growing a Ge_{1-y}Sn_{y} barrier layer over the Ge₁₋ₓSnₓ channel layer to form a two-dimensional hole gas in the Ge₁₋ₓSnₓ channel layer;
etching the Ge₁₋ₓSnₓ channel layer and the Ge_{1-y}Sn_{y} barrier layer to form a first opening and a second opening in the Ge₁₋ₓSnₓ channel layer and the Ge_{1-y}Sn_{y} barrier layer;
depositing a first source/drain electrode and a second source/drain electrode in the first opening and the second opening, respectively; and
forming a first gate electrode over the Ge_{1-y}Sn_{y} barrier layer.

2. The method of claim 1, wherein x>y.

3. The method of claim 1, wherein 0<x≤30%.

4. The method of claim 1, wherein the Ge_{1-y}Sn_{y} barrier layer is in the metastable state.

5. The method of claim 1, further comprising forming a second gate electrode over the Ge_{1-y}Sn_{y} barrier layer, wherein the second gate electrode is between the first gate electrode and the first source/drain electrode.

6. The method of claim 1, further comprising:
epitaxially growing a Ge_{1-z}Sn_{z} buffer layer over the substrate, and the Ge₁₋ₓSnₓ channel layer is epitaxially grown and in contact with the Ge_{1-z}Sn_{z} buffer layer, wherein x>z.

7. The method of claim 6, wherein a Sn atomic percentage of the Ge_{1-z}Sn_{z} buffer layer is decreased in a depth direction of the Ge_{1-z}Sn_{z} buffer layer.

8. A method comprising:
receiving a substrate;
performing a first epitaxy process to form a channel layer over the substrate, wherein the channel layer comprises Sn and Ge and has a first Sn atomic percentage;
determining a second Sn atomic percentage in a barrier layer based on the first Sn atomic percentage of the channel layer for increasing a spin-orbit coupling effect of the channel layer;
performing a second epitaxy process to form the barrier layer with the second Sn atomic percentage over and in contact with the channel layer;
forming a first source/drain electrode and a second source/drain electrode in the channel layer and the barrier layer; and
forming a gate electrode to cover the barrier layer and between the first source/drain electrode and the second source/drain electrode.

9. The method of claim 8, wherein the barrier layer is substantially free of N-type dopants and P-type dopants.

10. The method of claim 8, wherein the second Sn atomic percentage of the barrier layer is higher than the first Sn atomic percentage of the channel layer.

11. The method of claim 8, wherein the barrier layer further comprises Ge.

12. The method of claim 11, wherein a Ge atomic percentage in the channel layer is lower than a Ge atomic percentage in the barrier layer.

13. The method of claim 8, further comprising:
performing a third epitaxy process to form a buffer layer over the substrate and prior to performing the first epitaxy process.

14. The method of claim 13, wherein the buffer layer comprises Sn and Ge.

15. A method comprising:
epitaxially growing a channel stack over a substrate, wherein the channel stack is a heterostructure and comprises:
a channel layer comprising a first metal-containing binary compound material; and
a barrier layer in contact with the channel layer and comprising a second metal-containing binary compound material, wherein a metal atomic percentage of the first metal-containing binary compound material is higher than a metal atomic percentage of the second metal-containing binary compound material;
forming source/drain electrodes over the substrate and in contact with the channel layer;
depositing a gate dielectric layer to cover the channel stack; and
forming a gate electrode over the gate dielectric layer and the channel stack.

16. The method of claim 15, wherein the metal atomic percentage of the first metal-containing binary compound material is not higher than about 30%.

17. The method of claim 15, wherein the metal atomic percentage of the second metal-containing binary compound material is not higher than about 30%.

18. The method of claim 15, wherein the channel layer is in a metastable state.

19. The method of claim 15, wherein the channel stack further comprises a buffer layer under the channel layer and comprising a third metal-containing binary compound material, wherein the metal atomic percentage of the first metal-containing binary compound material is higher than a metal atomic percentage of the third metal-containing binary compound material.

20. The method of claim 15, wherein the first metal-containing binary compound material is GeSn.
